(19) United States
(12) Patent Application Publication
(10) Pub. No.: US 2025/0096518 A1
(43) Pub. Date: Mar. 20, 2025

(54) SEMICONDUCTOR LASER AND PROJECTOR

(71) Applicant: ams-OSRAM International GmbH, Regensburg (DE)

(72) Inventors: Christoph EICHLER, Donaustauf (DE); Alfred LELL, Maxhütte-Haidhof (DE); Sven GERHARD, Alteglofsheim (DE)

(73) Assignee: ams-OSRAM International GmbH, Regensburg (DE)

(21) Appl. No.: 18/294,469

(22) PCT Filed: Jul. 7, 2022
(86) PCT No.: PCT/EP2022/068928

§ 371 Date: Feb. 1, 2024

(30) Foreign Application Priority Data
Aug. 2, 2021 (DE) 10 2021 119 999.9

(51) Int. Cl. H01S 5/02; H01S 5/028; H01S 5/10; H01S 5/323

(52) U.S. Cl. CPC H01S 5/0207; H01S 5/0286; H01S 5/1085; H01S 5/32341

(57) ABSTRACT

In at least one embodiment, the semiconductor laser includes a semiconductor layer sequence for generating laser radiation and a transparent substrate. The semiconductor layer sequence has a first facet which is designed for emitting the laser radiation, and a second facet opposite the first facet. The substrate has a first lateral surface on the first facet and a second lateral surface on the second facet. The first lateral surface is orientated at least in part obliquely to the first facet and/or the second lateral surface is orientated at least in part obliquely to the second facet.

### CROSS-REFERENCE TO RELATED APPLICATIONS

The present application is a national stage entry from International Application No. PCT/EP2022/068928, filed on Jul. 7, 2022, published as International Publication No. WO 2023/011845 A1 on Feb. 9, 2023, and claims priority to German Patent Application No. 10 2021 119 999.9, filed Aug. 2, 2021, the disclosures of all of which are hereby incorporated by reference in their entireties.

### FIELD

A semiconductor laser is specified. A projector with such a semiconductor laser is also specified.

### BACKGROUND

Documents US 2014/0 133 504 A1 and US 2013/0 230 067 A1 relate to semiconductor lasers with radiation-impermeable layers on a substrate. An ISLE method is described in document US 2016/0 027 959 A1.

An object to be achieved is to specify a semiconductor laser that emits laser radiation with a high beam quality.

This object is solved, inter alia, by a semiconductor laser and by a projector with the features of the independent patent claims. Preferred further embodiments are the subject of the dependent claims.

### SUMMARY

According to at least one embodiment, the semiconductor laser comprises a semiconductor layer sequence for generating a laser radiation.

The semiconductor layer sequence comprises at least one active zone which is configured to generate laser radiation by means of electroluminescence during operation. The semiconductor layer sequence is based in particular on a III-V semiconductor compound material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or an arsenide semiconductor compound material such as AlₙIn₁₋ₙ₋ₘGaₘAs or AlₙGaₘIn₁₋ₙ₋ₘAsₖP₁₋ₖ, where in each case 0≤n≤1, 0≤m≤1 and n+m≤1 as well as 0≤k<1. For example, 0<n≤0.8, 0.4≤m<1 and n+m≤0.95 as well as 0<k≤0.5 applies to at least one layer or to all layers of the semiconductor layer sequence. The semiconductor layer sequence may comprise dopants and additional components. For the sake of simplicity, however, only the essential components of the crystal lattice of the semiconductor layer sequence, that is, Al, As, Ga, In, N or P, are specified, even if these may be partially replaced and/or supplemented by small amounts of other substances.

The semiconductor layer sequence is preferably based on the AlₙIn₁₋ₙ₋ₘGaₘN material system.

According to at least one embodiment, the semiconductor laser comprises a substrate that is transparent to the laser radiation. The semiconductor layer sequence is deposited on the substrate. For example, the semiconductor layer sequence is grown on the substrate, so that the substrate is a growth substrate. In particular, the substrate is made of GaN or sapphire. The semiconductor layer sequence can be located directly on the substrate, that is, without an intermediate layer.

According to at least one embodiment, the semiconductor layer sequence comprises a first facet which is configured to emit the laser radiation. Furthermore, the semiconductor layer sequence comprises a second facet opposite the first facet. The second facet is either also configured to emit the laser radiation or the second facet is configured to reflect the laser radiation, in particular as a resonator end mirror surface. The first and/or the second facet can be provided with optically effective coatings. For example, there is an anti-reflective coating on the first facet and a highly reflective coating on the second facet.

According to at least one embodiment, the substrate comprises a first side surface at the first facet and a second side surface at the second facet. The first side surface may be directly adjacent to the first facet and, correspondingly, the second side surface may be directly adjacent to the second facet. Alternatively, there is a distance between the first side surface and the first facet and/or between the second side surface and the two facets.

Side surfaces are in particular those outer boundary surfaces of the substrate that are visible in plan view of the associated facet and/or boundary surfaces whose angle or mean angle to the associated facet is at most 75° or at most 60° or at most 45°. The side surfaces can be main surfaces of the substrate. A main surface is, for example, one of the six largest outer boundary surfaces of the substrate. Boundary surfaces of the substrate are separated from one another in particular by edges, whereby an angle of adjacent boundary surfaces is then preferably at least 60° or at least 80°. In other words, it is possible for neighboring boundary surfaces of the substrate, which comprise only a small angle to one another, to be understood as a common side surface and/or as partial surfaces of the side surface in question.

According to at least one embodiment, the first side surface is oriented completely or in places obliquely to the first facet and/or the second side surface is oriented completely or in places obliquely to the second facet.

In at least one embodiment, the semiconductor laser comprises a semiconductor layer sequence for generating a laser radiation and a transparent substrate. The semiconductor layer sequence comprises a first facet configured to emit the laser radiation and a second facet opposite the first facet. The substrate comprises a first side surface at the first facet and a second side surface at the second facet. The first side surface is oriented at least in places oblique to the first facet and/or the second side surface is oriented at least in places oblique to the second facet. In particular, an angle between the first side surface and the first facet and/or an angle between the second side surface and the second facet is at least so large that total internal reflection of the laser radiation occurs at the side surface in question, so that the laser radiation cannot leave the substrate at the side surface in question.

In the semiconductor laser described here, substrate modes can be suppressed by differently inclined surfaces.

In addition to inclined surfaces, there are two other methods in particular for blocking laser radiation from a substrate. For example, light-absorbing layers on a side surface can prevent the laser radiation from leaving the substrate. Furthermore, laser radiation propagating in the substrate can be attenuated by absorber layers in and/or under the substrate.

In contrast to this, the semiconductor laser described here primarily uses differently inclined surfaces in the laser area and in the substrate area to direct the light guided in the substrate away from the optical axis. The total internal reflection of the laser radiation at the semiconductor-air interface can be utilized.

Normally, the semiconductor layer sequence is broken to produce laser facets. This generates a facet that includes both the area of the epitaxial layers, that is, the laser area, and the substrate. In the semiconductor laser described here, the laser facet and the separation of the substrate are preferably generated in two separate steps. This generates not just one common facet, but two different facets comprising different normal vectors. In this way, the unwanted light propagating in the substrate can be directed in a different direction than the desired laser light. This means that absorbers or reflectors on the facet or in or on the substrate are no longer necessary. However, such absorbers or reflectors can be used additionally and/or in combination.

In the laser described here, differently inclined surfaces are therefore used in the laser area and in the substrate area in order to direct the light guided in the substrate away from the optical axis. The angles can be different in the horizontal and/or vertical direction. Advantageously, the angle of the substrate facet is selected so that the light guided in the substrate is directed away from the optical axis. The light can be deflected into a housing, for example, with only a slight angular difference to the laser facet. For example, the angle can be selected to be greater than or equal to the total internal reflection angle so that the decoupling of the substrate light in the direction of the optical axis is completely suppressed. The deflected substrate light can also be used to monitor the output power of the laser by directing it onto a photodiode.

The semiconductor laser described here enables a significant improvement in beam quality, as the unwanted light guided in the substrate is deflected and/or suppressed. This is essentially achieved by the different angle of the laser facet relative to the substrate surface. The laser facet, that is, the facet of the semiconductor layer sequence, can advantageously be generated by facet etching, which is cost-effective and enables the semiconductor laser to be tested while still in the wafer composite. The substrate surfaces can be generated using cost-effective methods such as sawing or stealth dicing.

By suitably selecting the angles of the side surfaces to the facets of the semiconductor layer sequence, the deflected substrate light can also be used to monitor the output power of the laser without having to divert laser light separately. This can increase efficiency.

Furthermore, it is not necessary that absorbing layers are required at a few μm distance from the active laser beam in order to avoid the substrate mode. This avoids the risk of negatively influencing the efficiency of the laser diode. There is also no need for a time-consuming single-array process and absorber coating process.

According to at least one embodiment, the semiconductor laser is gain-guided. Alternatively, the semiconductor laser is index-guided and then preferably comprises a ridge waveguide.

In the following, for the sake of linguistic simplification, the term side surface and associated facet is usually used. This means either the pair of first facet and first side surface or alternatively the pair of second facet and second side surface, but this can also mean both pairs, that is, first facet and first side surface as well as second facet and second side surface.

According to at least one embodiment, the facet and the associated side surface run oblique to each other when viewed in top view on the semiconductor layer sequence. In particular, top view also refers to a vertical view of a top surface of the substrate on which the semiconductor layer sequence is applied. In other words, the facet and the associated side surface comprise different horizontal orientations.

According to at least one embodiment, when viewed in a sectional view through the semiconductor layer sequence along a longitudinal axis of the resonator and/or when viewed in a sectional view perpendicular to the top surface, the facet and the associated side surface run oblique to each other.

The longitudinal resonator axis is preferably delimited by the first and the second facet, wherein the first and the second facet may be oriented perpendicular to the longitudinal resonator axis. In other words, the facet and the associated side surface comprise different vertical orientations.

According to at least one embodiment, an angle between the at least one side surface, which is oriented oblique to the associated facet, and the associated facet is at least 1° or at least 2° or at least 10° or at least 24°. Alternatively or additionally, said angle is at most 65° or at most 45° or at most 30°. For example, this angle is at least so large that total internal reflection occurs at the side surface so that the laser radiation cannot leave the substrate at the side surface.

According to at least one embodiment, the at least one side surface, which is oriented oblique to the associated facet, is a flat surface. This means that the side surface in question does not comprise any kinks or curvatures. An average roughness, Ra, of this side surface is then, for example, at most 1 μm or at most 0.3 μm or at most 0.1 μm.

According to at least one embodiment, the at least one side surface, which is oriented oblique to the associated facet, is oriented parallel to a crystal plane of the substrate. For example, this side surface is generated by breaking, cleaving and/or scribing.

According to at least one embodiment, the at least one side surface, which is oriented oblique to the associated facet, is composed of a plurality of partial surfaces. Preferably, at least one, some or all of the relevant partial surfaces are planar surfaces, that is, surfaces without curvature. An angle between these partial surfaces, which can be separated from each other by edges, is, for example, at most 55° or at most 30° or at most 15° or at most 5°.

According to at least one embodiment, one or more or all of the partial surfaces are oriented oblique to the associated facet. This means that the side surface in question can be oriented parallel to the assigned facet in places.

According to at least one embodiment, the at least one side surface, which is oriented oblique to the associated facet, is a curved surface. It is possible that the side surface in question comprises a curvature that remains unchanged over this surface or also exhibits a varying curvature. The side surface in question can be curved along one direction in space, as in the case of a cylinder, or along two directions in space, as in the case of a spherical surface.

According to at least one embodiment, a portion of the at least one side surface which is oriented oblique to the associated facet is at least 95% or at least 80% or at least 60% or at least 30%. The remaining portion of the relevant side surface may be oriented parallel to the associated facet.

According to at least one embodiment, either only the first side surface is oriented at least in places oblique to the first facet or only the second side surface is oriented at least in places oblique to the second facet. This means that either the first or the second side surface is oriented completely parallel to the associated facet.

According to at least one embodiment, a distance between the facet in question and a region of the side surface oriented oblique thereto is at most 25 μm or at most 12 μm or at most 6 μm. This means that the obliquely oriented area is located close to the associated facet.

According to at least one embodiment, the at least one side surface, which is oriented oblique to the associated facet, is flush with the semiconductor layer sequence at an edge facing the semiconductor layer sequence. This applies in particular when viewed from above with respect to the semiconductor layer sequence and/or when viewed from above with respect to the main side of the substrate to which the semiconductor layer sequence is applied.

According to at least one embodiment, the at least one side surface, which is oriented oblique to the associated facet, projects beyond the semiconductor layer sequence at an edge facing the semiconductor layer sequence. This applies in particular when viewed from above with respect to the semiconductor layer sequence and/or when viewed from above with respect to the main side of the substrate to which the semiconductor layer sequence is applied. In other words, the side surface protrudes over the associated facet.

According to at least one embodiment, a step is present in the substrate between the at least one side surface, which is oriented oblique to the associated facet, and the semiconductor layer sequence. Such a step may also be referred to as a balcony.

According to at least one embodiment, a step height and/or a step width of the step are each at most 20 μm or at most 10 μm or at most 5 μm. Alternatively or additionally, the step height and/or the step width of the step are each at least 2 μm or at least 4 μm.

According to at least one embodiment, the semiconductor layer sequence comprises several laser emitters or is structured to form several laser emitters. Preferably, each of the laser emitters has its own resonator. The laser emitters can be operated electrically independently of one another. Alternatively, the laser emitters are electrically coupled to each other, for example, electrically connected in parallel. The laser emitters can form a laser bar.

In particular, each of the laser emitters comprises a separate first facet and a separate second facet. All first facets can be aligned parallel to each other, just as this is possible for all second facets.

According to at least one embodiment, the laser emitters are arranged parallel to each other on the substrate. In particular, the longitudinal resonator axes of the laser emitters are oriented parallel to each other.

According to at least one embodiment, the laser emitters end in a common plane. That is, there is a plane and/or a straight line that runs through all first facets and/or through all second facets of the laser emitters. It is possible that this common plane and/or straight line is oriented parallel to all first facets and/or to all second facets. Alternatively, this common plane and/or straight line is oriented oblique to all first facets and/or to all second facets.

According to at least one embodiment, the semiconductor laser further comprises one or more radiation block layers. The at least one radiation block layer is attached to the first side surface and/or to the second side surface and/or to a bottom surface of the substrate. The radiation block layer is configured to be reflecting or absorbing for the laser radiation. Absorbing means, for example, that a degree of absorption for the laser radiation is at least 75% or at least 90%. Reflecting means, for example, that a degree of reflection for the laser radiation is at least 75% or at least 90%.

According to at least one embodiment, the semiconductor laser comprises one or more photodiodes. The at least one photodiode is preferably attached to a longitudinal surface of the substrate. The longitudinal surface is oriented, for example, parallel or approximately parallel to the longitudinal axis of the resonator. The term approximately means, for example, an angular tolerance of at most 30° or at most 15° or at most 5°. This means that the longitudinal surface can be oriented transversely to the first side surface and transversely to the second side surface.

In addition, a projector is disclosed. The projector comprises one or more semiconductor lasers as described in connection with one or more of the above embodiments. Features of the semiconductor laser are therefore also disclosed for the projector and vice versa.

In at least one embodiment, the projector comprises at least one semiconductor laser and at least one optics downstream of the at least one semiconductor laser. The one optics or the plurality of optics are, for example, collimator lenses. However, the at least one optics may also comprise a beam guide, such as a movable mirror or a liquid crystal mask in combination with a mirror.

According to at least one embodiment, the projector comprises a housing in which the at least one semiconductor laser is mounted. The at least one side surface, which is oriented oblique to the associated facet, is configured to deflect laser radiation propagating in the substrate, so that the housing is configured as a barrier for laser radiation emerging from the substrate. In other words, the housing acts as a diaphragm and only allows a desired proportion of the laser radiation to pass, in particular that portion which emerges from the first facet.

### BRIEF DESCRIPTION OF THE DRAWINGS

In the following, a semiconductor laser described herein and a projector described herein are explained in more detail with reference to the drawing using exemplary embodiments. Identical reference signs indicate identical elements in the individual figures. However, no references to scale are shown; rather, individual elements may be shown in exaggerated size for better understanding.

In the figures:

FIG. 1 shows a schematic top view of an exemplary embodiment of a semiconductor laser described here,

FIGS. 2 and 3 show schematic top views of modified semiconductor lasers,

FIGS. 4 and 5 show the light emission of a modified semiconductor laser,

FIGS. 6 to 9 show schematic top views of exemplary embodiments of semiconductor lasers described here,

FIGS. 10 and 11 show schematic side views of exemplary embodiments of semiconductor lasers described herein,

FIGS. 12, 13 and 15 show schematic top views of exemplary embodiments of semiconductor lasers described herein,

FIG. 14 shows a schematic top view of a substrate for semiconductor lasers described here,

FIG. 16 shows a schematic top view of an exemplary embodiment of a projector with a semiconductor laser described here,

FIGS. 17 to 19 show schematic side views of exemplary embodiments of semiconductor lasers described herein, and

FIGS. 20 to 22 show schematic top views of exemplary embodiments of semiconductor lasers described herein.

### DETAILED DESCRIPTION

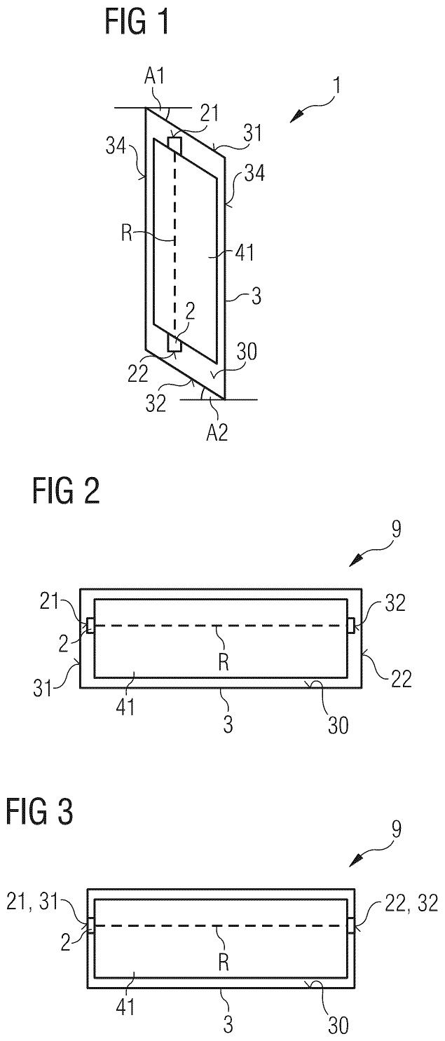

FIG. 1 shows an exemplary embodiment of a semiconductor laser 1. The semiconductor laser 1 comprises a substrate 3 and a semiconductor layer sequence 2 for generating laser radiation. The semiconductor layer sequence 2 is delimited along a longitudinal resonator axis R by a first facet 21 and by a second facet 22. For electrical contacting of the semiconductor layer sequence 2, a first electrode 41 is located on the semiconductor layer sequence 2 and optionally on a top surface 30 of the substrate, which is in particular made of at least one metal and/or transparent conductive oxide, TCO for short.

The substrate 3 is in particular a growth substrate for the semiconductor layer sequence 2. In this case, the semiconductor layer sequence 2 is preferably based on the material system AlInGaN and the substrate 3 is made of GaN or sapphire. The substrate 3 is transparent to the laser radiation generated in the semiconductor layer sequence 2. The laser radiation is, for example, green light or blue light, for example with a wavelength of maximum intensity of at least 435 nm and at most 580 nm.

A first side surface 31, which is associated with the first facet 21, and a second side surface 32 of the substrate 3, which is associated with the second facet 22, are oriented oblique to the facets 21, 22 when viewed from above. The side surfaces 31, 32 extend transversely to longitudinal surfaces 34 of the substrate 3. The longitudinal surfaces 34 can be oriented parallel to the longitudinal axis R of the resonator. The side surfaces 31, 32 are preferably flat surfaces which are oriented perpendicular to the top surface 30 according to FIG. 1.

Angles A1, A2 between the side surfaces 31, 32 and the associated facets 21, 22 are the same and are, for example, between 10° and 30° inclusive. Viewed from above, the substrate 3 and the top surface 30 thus comprise the shape of a parallelogram.

Optional anti-reflective coatings or highly reflective coatings on the facets 21, 22 as well as electrically insulating layers to prevent short circuits on the first electrode 41 are not shown to simplify the illustration.

Thus, the laser facets 21, 22 and the side surfaces 31, 32, also referred to as substrate facets, have different angles with respect to an optical axis along the longitudinal resonator axis R, so that the laser radiation in the substrate 3 is reflected or emerges in a different direction than the laser radiation guided along the longitudinal resonator axis R in the semiconductor layer sequence 2. To achieve this, the facets 21, 22 are preferably generated by facet etching. The side surfaces 31, 32 are generated, for example, by means of breaking, sawing, etching and/or laser cutting, such as stealth dicing or selective laser etching, ISLE for short. In stealth dicing, fracture nuclei are generated within the substrate by means of a focused separation laser; in contrast to a laser scribing process, in which material removal is carried out by the separation laser, in stealth dicing only fracture nuclei are induced in the material of the wafer by the separation laser.

FIGS. 2 and 3 show modified semiconductor lasers 9. In these modified semiconductor lasers 9, the facets 21, 22 and the side surfaces 31, 32 are aligned parallel to each other. In such modified semiconductor lasers 9 with a transparent substrate 3, laser radiation can couple from a waveguide of the semiconductor layer sequence 2 into the substrate 3 and propagate there. This so-called substrate mode is visible as interference in the optical far field, which can lead to imaging errors.

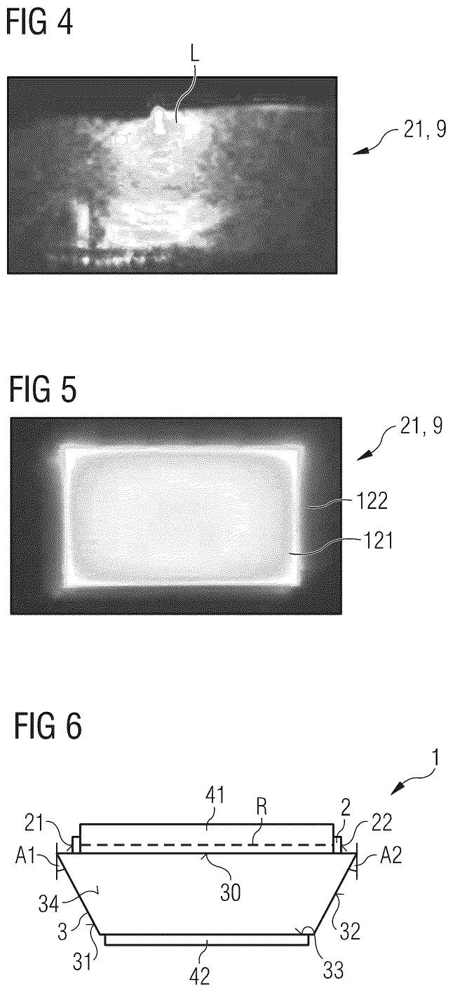

FIG. 4 shows a side surface 21 in operation of such a modified semiconductor laser 9 and FIG. 5 shows a projection surface 12 scanned with such a modified semiconductor laser 9. As can be seen in FIG. 4, in particular with InGaN lasers, laser radiation L is emitted from the substrate 3 in addition to the emission from the laser resonator. The area from which the substrate modes are emitted is much larger than the expansion of a main mode in the semiconductor layer sequence 2. In addition, the substrate modes are emitted at large beam angles.

In laser projection applications, the laser beam L must be focused on as small an area as possible. This area is drastically enlarged by the substrate light, which leads to image errors, particularly in laser projection applications. In the application, a disturbing halo 122 is created around the actual image 121, see FIG. 5.

In the semiconductor lasers 1 described here, however, the laser facet 21, 22 and the associated substrate facet 31, 32 have different vertical and/or horizontal angles with respect to the optical axis. This means that a normal vector on the laser facet 21, 22 is different from that on the associated substrate facet 31, 32. This makes it possible to prevent such halos 122 and to achieve high-quality emission of the laser radiation L.

The laser facet 21, 22 and the substrate facet 31, 32 can each be either etched or broken. The substrate facet 21, 22 can furthermore also be produced, for example, by stealth dicing, laser cutting or sawing, whereby any combinations for the production of the facets 21, 22, 31, 32 are conceivable. The first facet 21 and the second facet 22 of the semiconductor laser 1 and the first and second side surfaces 31, 32 of the substrate 3 can each be produced using the same or different methods.

FIGS. 6 to 11 show further exemplary embodiments of semiconductor lasers 1 in which at least one of the side surfaces 31, 32 is oriented oblique to the associated facet 21, 22 when viewed in a sectional view perpendicular to the top surface 30. This can also be referred to as a vertical inclination of the side surfaces 31, 32 relative to the associated facet 21, 22. In contrast, the side surfaces 31, 32 are inclined horizontally with respect to the associated facet 21, 22 as shown in FIG. 1, that is, as seen in plan view of the top surface 30.

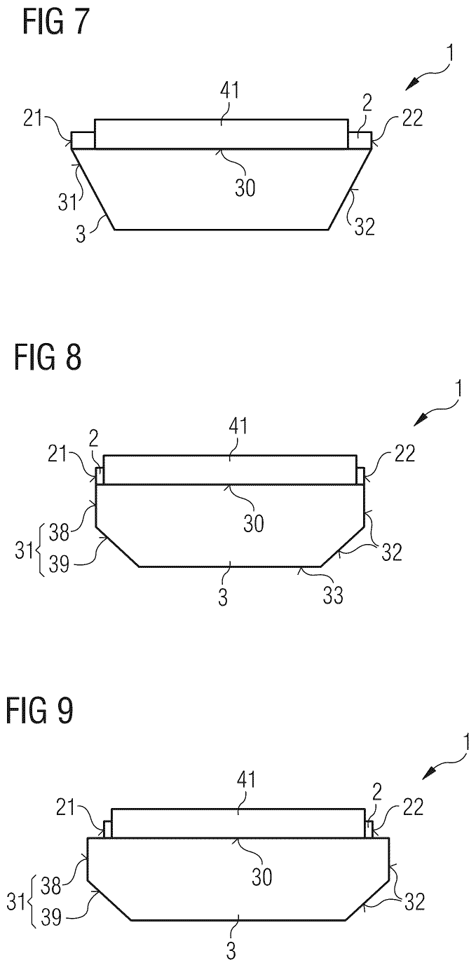

According to FIGS. 6 and 7, the side surfaces 31, 32 are flat surfaces perpendicular to the drawing plane and the substrate 3 is a symmetrical trapezoid when viewed in cross-section, but may also be shaped as an asymmetrical trapezoid. The longitudinal resonator axis R is oriented parallel to the top surface 30 and parallel to a bottom surface 33. A second electrode 42 is located on the bottom surface 33 of the substrate 3, in the case of an electrically conductive substrate 3, such as a GaN substrate. Electrical insulation between the first electrode 41 and the substrate 3 is not shown. Alternatively, the second electrode 42 can also be located on the top surface 30 if the substrate 3 is electrically insulating, for example, in the case of a sapphire substrate.

FIG. 6 shows that the facets 21, 22 are set back relative to the side surfaces 31, 32. This means that the substrate 3 protrudes beyond the semiconductor layer sequence 2 as an extension of the longitudinal axis R of the resonator. In contrast, the substrate 3 and the semiconductor layer sequence 2 are flush with each other as shown in FIG. 7.

FIGS. 8 and 9 illustrate that the side surfaces 31, 32 are each composed of two partial surfaces 38, 39. The partial surfaces 38 are oriented parallel to the facets 21, 22 and the partial surfaces 39 are oriented oblique to the facets 21, 22, whereby the partial surfaces 38, 39 can be separated from each other by an edge. The partial surfaces 38 oriented parallel to the facets 21, 22 are located closer to the semiconductor layer sequence 2 than the obliquely oriented partial surfaces 39, which can extend to the bottom surface 33.

An expansion of the parallel partial surfaces 38 in the direction perpendicular to the top surface 30 is preferably at most 30 μm or at most 10 μm or at most 5 μm. For example, a total thickness of the substrate 3 is between 50 μm and 200 μm inclusive. Viewed in top view onto the facets 21, 22, an area of the obliquely oriented partial surfaces 31, 32 preferably appears to be at least 30% or at least 60% or at least 90% as large as a total area of the respectively associated side surface 31, 32 resulting from this angle of view.

The partial surfaces 38, 39 can be produced, for example, using a wedge-shaped and optionally additionally stepped saw blade.

FIG. 8 shows, analogous to FIG. 6, that the facets 21, 22 are set back relative to the side surfaces 31, 32. In contrast, the substrate 3 and the semiconductor layer sequence 2 are flush with each other as shown in FIG. 9, analogous to FIG. 7.

Other than shown, in FIGS. 6 to 9 the facets 21, 22 may also be subdivided into partial surfaces, in particular in the same way as the side surfaces 31, 32.

In all other respects, the explanations on FIGS. 1 to 5 apply in the same way to FIGS. 6 to 9, and vice versa.

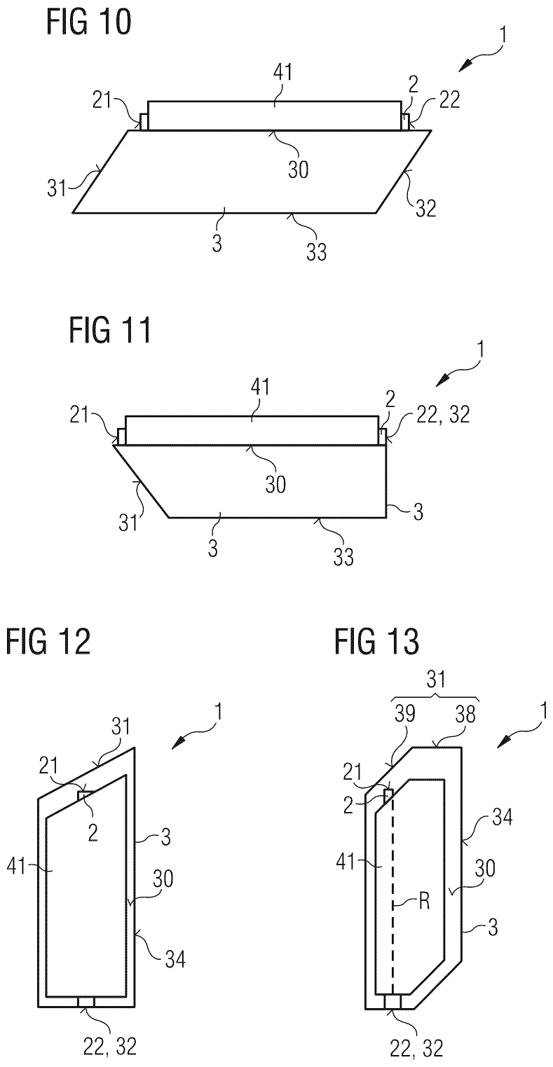

In the exemplary embodiment shown in FIG. 10, the substrate 3 is shaped as a parallelogram when viewed in sectional view perpendicular to the top side 30. Such oblique side surfaces 31, 32 can be generated, for example, by breaking substrates with a so-called offcut or by means of semipolar substrates. Offcut means that a crystal plane of the side surfaces 31, 32 is oriented oblique to the facets 21, 22.

According to FIG. 11, only one of the side surfaces 31 is oriented oblique to the associated facet 21. The surfaces 22, 32 are aligned parallel to each other. This can apply in the same way to all other exemplary embodiments, in particular to the semiconductor lasers of FIGS. 6 to 10 with vertically different inclinations.

In the same way, with horizontally different inclinations, only one of the side surfaces 31 can be oriented obliquely, see FIG. 12.

In all other respects, the explanations on FIGS. 1 to 10 apply in the same way to FIGS. 11 and 12, and vice versa.

Analogous to FIGS. 6 to 9 for vertically subdivided side surfaces 31, 32, it is shown in FIG. 13 that the side surfaces 31, 32 are horizontally subdivided, that is, as seen in plan view of the top surface 30. The same applies to the facets 21, 22.

Areas of the side surfaces 31, 32 lying opposite each other along the longitudinal axis R of the resonator can thus be oriented oblique to each other, and not only oblique to the facet 21. In this case, the substrate 3 can have a point-symmetrical shape when viewed in top view of the top surface 30. In top view of the first facet 21, the partial surfaces 38, 39 can appear to be of the same size.

In all other respects, the explanations on FIGS. 1 to 12 apply in the same way to FIG. 13, and vice versa.

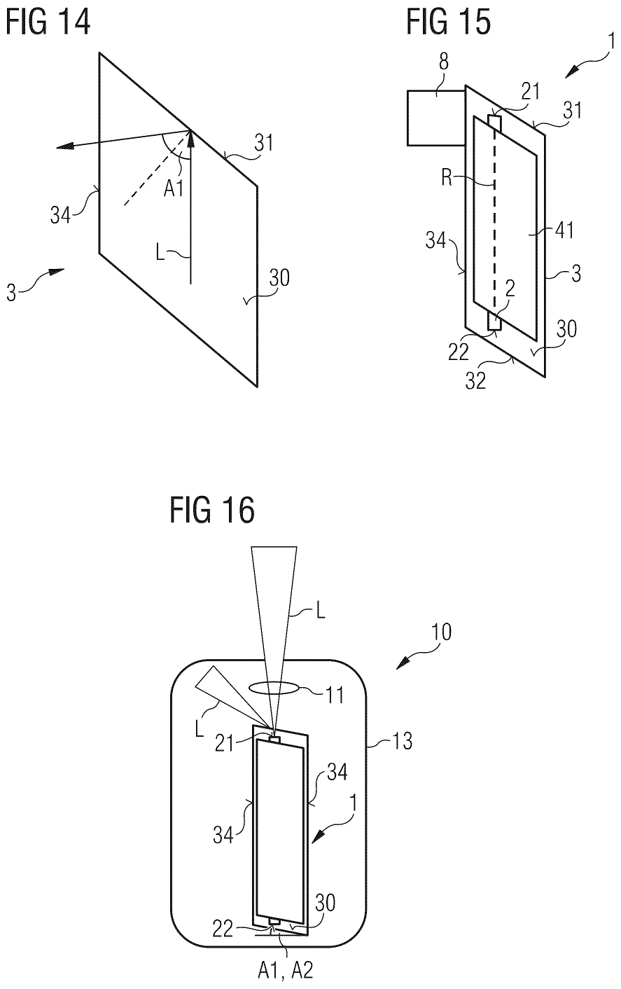

In FIG. 14, a reflection of the laser radiation L at the side surface 31 is drawn in more detail. The light L strikes the side surface 31 at an angle A1 with respect to a normal.

Preferably, an angle A1, A2 is selected for the substrate facets 31, 32 which is greater than or equal to a total internal reflection angle Atr=arcsin(1/n), where n is the refractive index of the substrate 3 for the laser radiation L. The following applies to GaN: Atr˜24°.

If A1, A2 is selected, for example, at 45° or approximately 45°, as shown as an example in FIG. 14, the light L guided in the substrate 3 can be emitted at the longitudinal surface 34 of the semiconductor laser 1. A photodiode 8 can be placed there to control an output power of the laser radiation L, see FIG. 15. The semiconductor laser 1 of FIG. 15 corresponds to that of FIG. 1, whereby in the same way the semiconductor lasers 1 of the other exemplary embodiments can be equipped with one or more photodiodes 8. In the semiconductor lasers of FIGS. 6 to 11, such a photodiode 8 could then also be placed on the bottom surface 33.

In all other respects, the explanations on FIGS. 1 to 13 apply in the same way to FIGS. 14 and 15, and vice versa.

FIG. 16 illustrates a projector 10 comprising at least one semiconductor laser 1 according to one of the preceding exemplary embodiments, such as the semiconductor laser of FIG. 1. Further, the projector 10 comprises optics 11 for shaping the laser radiation L and a housing 13, such as a TO housing. In contrast to what is shown, the optics 11 can also close an opening in the housing 13.

The laser radiation L guided in the substrate 3 is deflected by the side surfaces 31, 32 so that it does not hit the optics 11 but the opaque housing 13 and thus does not leave the housing 13. In this case, the angle A1, A2 is preferably smaller than the angle for total internal reflection.

In FIG. 16, only one semiconductor laser 1 is shown for the sake of simplicity. In particular, however, semiconductor lasers 1 are present for generating blue, green and red light, whereby preferably the semiconductor lasers 1 for blue and green light are equipped with at least one obliquely oriented side surface 31, 32. The optics 11 can then also comprise a movable mirror and/or a liquid crystal mask for beam guidance, not shown.

In all other respects, the explanations on FIGS. 1 to 15 apply in the same way to FIG. 16, and vice versa.

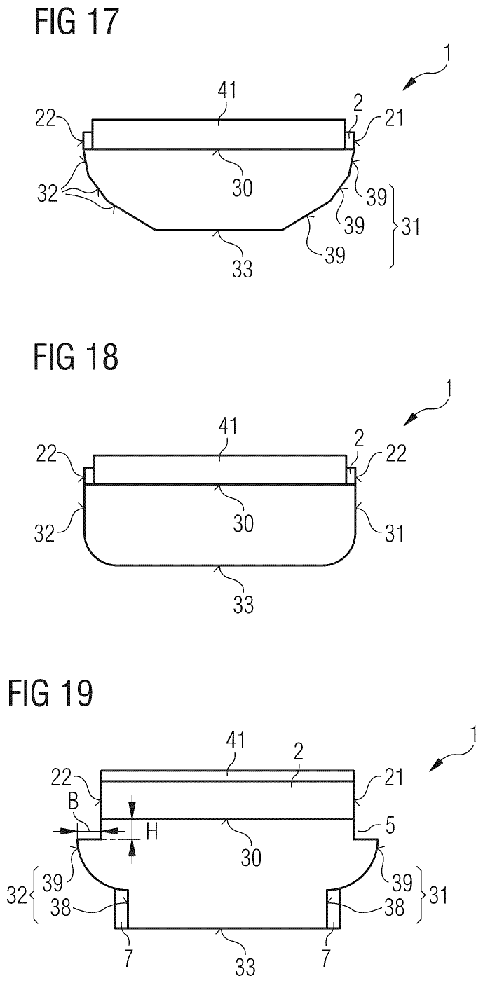

The side surfaces 31, 32 of the semiconductor laser 1 of FIG. 17 are divided into at least three of the oblique sub-surfaces 39. The partial surfaces 39 comprise increasingly smaller angles relative to the top surface 30 in the direction towards the bottom surface 33.

FIG. 18 shows that the side surfaces 31, 32 need not be formed by straight surfaces or partial surfaces, but can also be curved surfaces. In FIG. 18, the shape of the substrate 3, as shown in FIG. 17, is approximated.

Such a design of at least one of the side surfaces 31, 32 according to FIG. 17 or 18 can also be used for horizontally inclined side surfaces 31, 32, similar to FIG. 13.

In all other respects, the comments on FIGS. 1 to 16 apply in the same way to FIGS. 17 and 18, and vice versa.

In the exemplary embodiment of FIG. 19, it can be seen that curved partial surfaces 39 can be combined with flat partial surfaces 38, as is also possible in all other exemplary embodiments. The curved partial surfaces 39 are preferably located closer to the top surface 30 than the partial surfaces 38 oriented parallel to the facets 21, 22.

Furthermore, it can be seen in FIG. 19 that the substrate 3 optionally comprises a step 5 on at least one of the facets 21, 22 or on each one of the facets 21, 22. At the steps 5, the substrate 3 and the semiconductor layer sequence 2 are flush with each other. The steps 5 are generated, for example, during etching, such as dry etching, of the facets 21, 22. This means that the substrate 3 can be etched during this etching process. Due to the steps 5, the side surfaces 31, 32 are arranged spaced from the facets 21, 22.

A step height H of the steps 5 is preferably small and is, for example, between 1 μm and 7 μm inclusive or between 1 μm and 5 μm inclusive. A step width B in the direction parallel to the top surface 30 is preferably just as small and is, for example, also between 1 μm and 7 μm inclusive or between 1 μm and 5 μm inclusive.

Such steps 5 are preferably also present in all other exemplary embodiments in which the facets 21, 22 are not flush with the side surfaces 31, 32.

Finally, FIG. 19 shows that at least one radiation block layer 7 is optionally present on the substrate 3. For example, the radiation block layer 7 partially covers the side surfaces 31, 32, but other than shown may also completely cover the side surfaces 31, 32. It is also possible that the radiation block layer 7 partially or completely covers the bottom surface 33 or the steps.

One or more such reflecting or absorbing radiation blocking layers 7 may be present in all other exemplary embodiments as well.

In all other respects, the explanations on FIGS. 1 to 18 apply in the same way to FIG. 19, and vice versa.

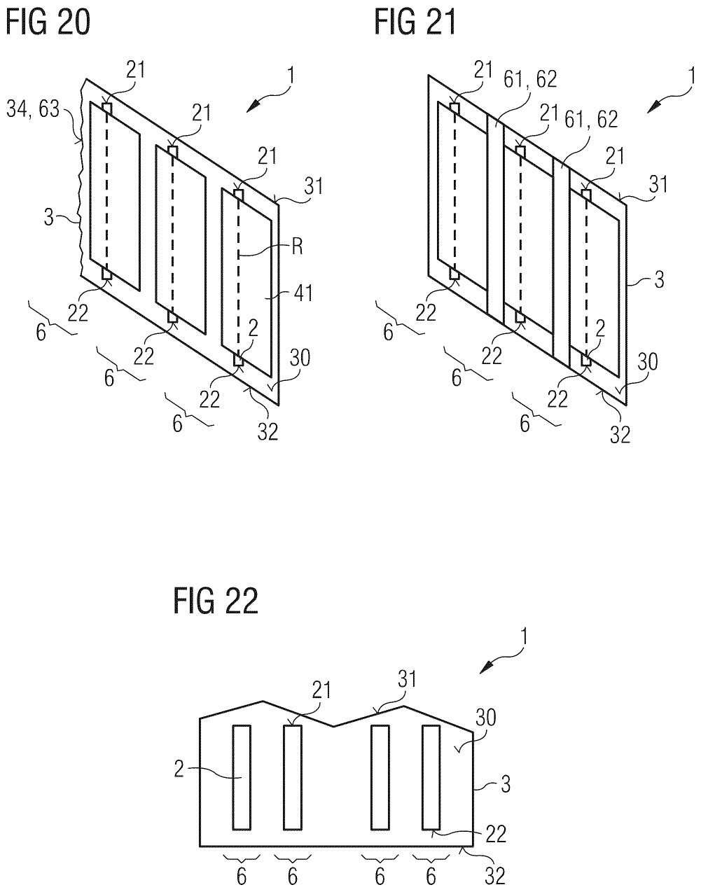

The semiconductor laser 1 of FIG. 20 comprises a plurality of laser emitters 6, wherein each of the laser emitters 6 comprises a resonator with one of the longitudinal resonator axes R, and the longitudinal resonator axes R are preferably oriented parallel to each other. It is possible that all first facets 21 and all second facets 22 lie on a straight line, as viewed in top view of the top surface 30 of the common substrate 3. All laser emitters 6 are thus assigned common and flat side surfaces 31, 32. The substrate 3 is shaped in particular as a parallelogram.

It is also illustrated in FIG. 20 that at least one of the longitudinal surfaces 34 can be provided with a roughening 63 in places or over the entire surface, for example by sawing, laser cutting and/or stealth dicing. This efficiently decouples the light laterally and prevents multiple reflections or ring modes from forming in the substrate 3. Such a roughening 63 on at least one of the longitudinal surfaces 34 may also be present in all other exemplary embodiments.

In all other respects, the explanations on FIGS. 1 to 19 apply in the same way to FIG. 20, and vice versa.

In the semiconductor laser 1 of FIG. 21, there is an optional trench 61 between adjacent laser emitters 6 in the substrate 3 on the top surface 30. The trenches 61 can be partially or completely filled with a blocking material 62 that is impenetrable for the laser radiation L.

Otherwise, the explanations on FIG. 20 apply in the same way to FIG. 21, and vice versa.

According to FIG. 22, the second facets 32 of the laser emitters 6 are each arranged parallel to the associated second side surface 32, whereby all laser emitters 6 can be of the same length. The first facets 21 are each oriented oblique to the first side surface 31. Preferably, the first facets 21 all lie completely in a common plane. This simplifies optical handling of the laser radiation from the laser emitters 6.

The first side surface 31 has a sawtooth shape, for example, when viewed from above with respect to the top surface 30. An angle between the first side surface 31 and the first facets 21 may be the same for all first facets 21.

In all other respects, the comments on FIGS. 20 and 21 apply in the same way to FIG. 22, and vice versa.

The above remarks on the individual emitters thus preferably also apply to multiple emitters and/or arrays of laser emitters 6, whereby the various laser emitters 6 may have the same laser facet angle and/or substrate facet angle, or may also comprise at least partially different angles. The exemplary embodiments of FIGS. 20 to 22 each comprise only horizontally inclined side surfaces 21, 22; however, vertically inclined side surfaces 21, 22, for example as illustrated in FIGS. 6 to 11, can also be used in the same way.

In the above exemplary embodiments, the side surfaces 31, 32 are each inclined in either a vertical or horizontal direction relative to the facets 21, 22. It is also possible for an inclination to be present in both the vertical and horizontal directions. For example, the exemplary embodiment of FIG. 1 can be combined with the exemplary embodiments of FIGS. 6 to 10.

The invention described herein is not limited by the description based on the exemplary embodiments. Rather, the invention includes any new feature as well as any combination of features, which includes in particular any combination of features in the patent claims, even if this feature or combination itself is not explicitly stated in the patent claims or exemplary embodiments.

1. A semiconductor laser (1) comprising:
a semiconductor layer sequence for generating a laser radiation, and
a substrate which is transparent to the laser radiation and to which the semiconductor layer sequence is applied,
wherein
the semiconductor layer sequence comprises a first facet which is configured for emitting the laser radiation, and a second facet opposite the first facet,
the substrate comprises a first side surface at the first facet and a second side surface at the second facet,
the first side surface is oriented at least in places obliquely to the first facet and/or the second side surface is oriented at least in places obliquely to the second facet, and
an angle between the first side surface and the first facet and/or an angle between the second side surface and the second facet is at least so large that total internal reflection of the laser radiation occurs at the relevant side surface (31,32), so that the laser radiation cannot leave the substrate at the relevant side surface.

2. The semiconductor laser according to claim 1,
wherein the first facet and the first side surface and/or the second facet and the second side surface are oblique to each other when viewed in top view of the semiconductor layer sequence.

3. The semiconductor laser according to claim 1,
wherein the first facet and the first side surface and/or the second facet and the second side surface run oblique to each other when viewed in a sectional view through the semiconductor layer sequence along a longitudinal axis of the resonator.

4. The semiconductor laser according to claim 1,
wherein the angle between the first side surface and the first facet and/or the angle between the second side surface and the second facet is at least 24° and at most 45°,
wherein the semiconductor layer sequence is based on the material system AlInGaN and the substrate is a GaN substrate.

5. The semiconductor laser according to claim 1,
wherein the first side surface, when oriented oblique to the first facet, and/or the second side surface, when oriented oblique to the second facet, is a flat surface.

6. The semiconductor laser according to claim 5,
wherein the first side surface, when oriented oblique to the first facet, and/or the second side surface, when oriented oblique to the second facet, is oriented parallel to a crystal plane of the substrate and is produced by breaking.

7. The semiconductor laser according to claim 1,
wherein the first side surface, when oriented oblique to the first facet, and/or the second side surface, when oriented oblique to the second facet, is composed of a plurality of planar partial surfaces,
the partial surfaces being separated from one another by edges and at least one of the partial surfaces being oriented oblique to the associated facet.

8. The semiconductor laser according to claim 1,
wherein the first side surface, when oriented oblique to the first facet, and/or the second side surface, when oriented oblique to the second facet, is a curved surface.

9. The semiconductor laser according to claim 1,
wherein a proportion of the first side surface, which is oriented oblique to the first facet, and/or a proportion of the second side surface, which is oriented oblique to the second facet, is at least 60%.

10. The semiconductor laser according to claim 1,
wherein either only the first side surface is oriented at least in places oblique to the first facet or only the second side surface is oriented at least in places oblique to the second facet.

11. The semiconductor laser according to claim 1,
wherein a distance between the first facet and a region of the first side surface oriented oblique thereto and/or a distance between the second facet and a region of the second side surface oriented oblique thereto is at most 12 μm.

12. The semiconductor laser according to claim 1,
wherein, as seen in plan view of the semiconductor layer sequence, the first side surface, when oriented obliquely to the first facet, and/or the second side surface, when oriented obliquely to the second facet, ends flush with the semiconductor layer sequence at an edge next to the semiconductor layer sequence.

13. The semiconductor laser according to claim 1,
in which, seen in plan view of the semiconductor layer sequence, the first side surface, when oriented obliquely to the first facet, and/or the second side surface, when oriented obliquely to the second facet, projects beyond the semiconductor layer sequence at an edge next to the semiconductor layer sequence.

14. The semiconductor laser according to claim 13,
wherein there is a step in the substrate between the first side surface, when oriented obliquely to the first facet, and/or the second side surface, when oriented obliquely to the second facet, and the semiconductor layer sequence,
wherein a step height and a step width of the step each being at most 10 μm.

15. The semiconductor laser according to claim 1,
wherein the semiconductor layer sequence comprises a plurality of laser emitters or is structured into a plurality of laser emitters,
wherein the laser emitters being arranged parallel to each other on the substrate.

16. The semiconductor laser according to claim 15,
wherein the laser emitters end in a common plane.

17. (canceled)

18. The semiconductor laser according to claim 1,
further comprising at least one photodiode attached to a longitudinal surface of the substrate,
wherein the longitudinal surface is oriented transversely to the first side surface and transversely to the second side surface.

19. A projector comprising at least one semiconductor laser according to claim 1,
further comprising at least one optics which is arranged downstream of the at least one semiconductor laser.

20. The projector according to claim 19,
further comprising a housing in which the at least one semiconductor laser is mounted,
wherein the first side surface, when oriented oblique to the first facet, and/or the second side surface, when oriented oblique to the second facet, is configured for deflection of laser radiation propagating in the substrate, and
wherein the housing is configured as a barrier for laser radiation emerging from the substrate.

21. A semiconductor laser (1) comprising:
a semiconductor layer sequence for generating a laser radiation; and
a substrate which is transparent to the laser radiation and to which the semiconductor layer sequence is applied,
wherein
the semiconductor layer sequence comprises a first facet which is configured for emitting the laser radiation, and a second facet opposite the first facet,
a longitudinal resonator axis is delimited by the first and the second facet, the first and the second facet are oriented perpendicular to the longitudinal resonator axis,
the substrate comprises a first side surface at the first facet and a second side surface at the second facet,
the first side surface is oriented at least in places obliquely to the first facet and/or the second side surface is oriented at least in places obliquely to the second facet, seen in plan view of a top surface of the substrate, the semiconductor layer sequence is applied on, and
an angle between the first side surface and the first facet and/or an angle between the second side surface and the second facet is at least so large that total internal reflection of the laser radiation guided along the longitudinal resonator axis occurs at the relevant side surface, so that the laser radiation cannot leave the substrate at the relevant side surface.
